(19) United States
(12) Patent Application Publication
(10) Pub. No.: US 2025/0358998 A1
(43) Pub. Date: Nov. 20, 2025

(54) SEMICONDUCTOR DEVICE

(71) Applicant: SAMSUNG ELECTRONICS CO., LTD., Suwon-si (KR)

(72) Inventors: Hyojin KIM, Suwon-si (KR); Kyung Hee Cho, Suwon-si (KR); Donghoon Hwang, Suwon-si (KR); Choonghwan Kim, Suwon-sii (KR); Byungho Moon, Suwon-si (KR)

(73) Assignee: SAMSUNG ELECTRONICS CO., LTD., Suwon-si (KR)

(21) Appl. No.: 18/921,735

(22) Filed: Oct. 21, 2024

(30) Foreign Application Priority Data
May 14, 2024 (KR) 10-2024-0063448

(51) Int. Cl. H10B 10/00

(52) U.S. Cl. CPC H10B 10/125

(57) ABSTRACT

A semiconductor device may include: a first lower active pattern extending in a first direction and including a first lower channel pattern; a second lower active pattern extending in the first direction; a first upper active pattern extending in the first direction; a second upper active pattern extending in the first direction; a first gate structure extending in the second direction; a second gate structure extending in the second direction; a first lower source/drain pattern disposed on one side of the first lower channel pattern; a first upper source/drain pattern disposed on one side of the first upper channel pattern; a second lower source/drain pattern disposed on one side of the second lower channel pattern; and a second upper source/drain pattern disposed on one side of the second upper channel pattern.

### CROSS-REFERENCE TO RELATED APPLICATION

This application claims priority to Korean Patent Application No. 10-2024-0063448, filed in the Korean Intellectual Property Office on May 14, 2024, the entire contents of which are hereby incorporated by reference.

### BACKGROUND

### 1. Field

The present disclosure relates to a semiconductor device.

### 2. Description of Related Art

A semiconductor device is a core component used to control or amplify an electrical signal in an electronic device, and various types of semiconductor devices may be manufactured. For example, a memory device may be mainly used to store and retrieve data, while a non-memory device may be used to control or amplify an electrical signal. The semiconductor device is a core component of an electronic device and plays an important role in various fields including computers, communication equipment, consumer electronics, etc.

Among the semiconductor devices, the static random access memory (SRAM) is a memory device that generally provides high operating speed with low operating power because it does not require data refresh. In general, an SRAM cell includes two pass transistors, and two inverters forming a flip-flop circuit.

When configuring the SRAM cell, six transistors are arranged in a single SRAM cell, and this makes it difficult to improve the degree of integration of the SRAM cell.

### SUMMARY

In order to solve one or more problems (e.g., the problems described above and/or other problems not explicitly described herein), the present disclosure provides a semiconductor device with improved integration and device performance.

According to one or more embodiments of the present disclosure, the first transistor group disposed at the first level and the second transistor group disposed at the second level may be overlapped with each other in the vertical direction, thereby improving integration of the semiconductor device.

According to one or more example embodiments, a semiconductor device may include: a first lower active pattern extending in a first direction and including a first lower channel pattern; a second lower active pattern extending in the first direction and spaced apart from the first lower active pattern in a second direction intersecting the first direction, wherein the second lower active pattern includes a second lower channel pattern; a first upper active pattern extending in the first direction and spaced apart from the first lower active pattern in a third direction intersecting the first direction and the second direction, wherein the first upper active pattern includes a first upper channel pattern; a second upper active pattern extending in the first direction and spaced apart from the second lower active pattern in the third direction, wherein the second upper active pattern includes a second upper channel pattern; a first gate structure extending in the second direction and intersecting the first lower active pattern and the first upper active pattern; a second gate structure extending in the second direction and intersecting the second lower active pattern and the second upper active pattern; a first lower source/drain pattern disposed on one side of the first lower channel pattern; a first upper source/drain pattern disposed on one side of the first upper channel pattern; a second lower source/drain pattern disposed on one side of the second lower channel pattern; and a second upper source/drain pattern disposed on one side of the second upper channel pattern. The first lower source/drain pattern and the first upper source/drain pattern may have different conductivity types, and the second lower source/drain pattern and the second upper source/drain pattern may have the same conductivity type.

According to one or more example embodiments, a semiconductor device may include: a first transistor group disposed at a first level, wherein the first transistor group includes a first pull-up transistor, a second pull-up transistor, and a first pass transistor; a second transistor group disposed at a second level different from the first level, wherein the second transistor group includes a first pull-down transistor, a second pull-down transistor, and a second pass transistor; a first power line connected to a source pattern of the first pull-up transistor; and a second power line connected to a source pattern of the first pull-down transistor. A drain pattern of the first pull-up transistor, a drain pattern of the first pull-down transistor, and a drain pattern of the first pass transistor may be electrically connected through a first node. A drain pattern of the second pull-up transistor, a drain pattern of the second pull-down transistor, and a drain pattern of the second pass transistor may be electrically connected through a second node. The first pass transistor and the second pass transistor may overlap in a first direction, the first pull-up transistor and the first pull-down transistor may overlap in the first direction, and the first direction may be perpendicular to an upper surface of the first power line.

According to one or more example embodiments, a semiconductor device may include: a first lower active pattern extending in a first direction; a second lower active pattern extending in the first direction and spaced apart from the first lower active pattern in a second direction intersecting the first direction; a first upper active pattern extending in the first direction and spaced apart from the first lower active pattern in a third direction intersecting the second direction; a second upper active pattern extending in the first direction and spaced apart from the second lower active pattern in the third direction; a first pull-up transistor and a second pull-up transistor disposed on the first lower active pattern; a first pull-down transistor and a second pull-down transistor disposed on the first upper active pattern; a first pass transistor disposed on the second lower active pattern; a second pass transistor disposed on the second upper active pattern; a first power line connected to a source pattern of the first pull-up transistor; and a second power line connected to a source pattern of the first pull-down transistor. The first power line and the second power line may be disposed below the first lower active pattern. A drain pattern of the first pull-up transistor, a drain pattern of the first pull-down transistor, and a drain pattern of the first pass transistor may be electrically connected through a first node. A drain pattern of the second pull-up transistor, a drain pattern of the second pull-down transistor, and a drain pattern of the second pass transistor may be electrically connected through a second node. The first pass transistor and the second pass transistor may overlap in the third direction. The first pass transistor, the second pass transistor, the first pull-down transistor, the second pull-down transistor, the first pull-up transistor, and the second pull-up transistor may include a plurality of sheet patterns.

According to one or more example embodiments, a semiconductor device may include: a first transistor group disposed at a first level, wherein the first transistor group includes a first pull-up transistor, a second pull-up transistor, and a first pass transistor; and a second transistor group disposed at a second level different from the first level, wherein the second transistor group includes a first pull-down transistor, a second pull-down transistor, and a second pass transistor. The first pass transistor and the second pass transistor may overlap in a first direction. The first pull-up transistor and the first pull-down transistor may overlap in the first direction. The second pull-up transistor and the second pull-down transistor may overlap in the first direction. The first pull-up transistor and the second pull-up transistor may be first conductivity type transistors. The first pull-down transistor, the second pull-down transistor, the first pass transistor, and the second pass transistor may be second conductivity type transistors. The first conductivity type transistors may have a different conductivity type from the second conductivity type transistors.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a circuit diagram provided to explain a semiconductor device according to one or more embodiments of the present disclosure;

FIG. 2 is a schematic diagram provided to explain a semiconductor device according to one or more embodiments of the present disclosure;

FIG. 3 is a layout diagram showing a semiconductor device according to one or more embodiments of the present disclosure;

FIG. 4 is a layout diagram showing a semiconductor device according to one or more embodiments of the present disclosure;

FIG. 5 is a cross-sectional view taken along line A-A of FIGS. 3 and 4;

FIG. 6 is a cross-sectional view taken along line B-B of FIGS. 3 and 4;

FIG. 7 is a cross-sectional view taken along line C-C of FIGS. 3 and 4;

FIG. 8 is a layout diagram showing a semiconductor device according to one or more embodiments of the present disclosure;

FIG. 9 is a layout diagram showing a semiconductor device according to one or more embodiments of the present disclosure;

FIG. 10 is a schematic diagram showing a semiconductor device according to one or more embodiments of the present disclosure;

FIG. 11 is a diagram showing an intermediate stage, to show a method for manufacturing a semiconductor device according to one or more embodiments of the present disclosure;

FIG. 12 is a diagram showing an intermediate stage, to show a method for manufacturing a semiconductor device according to one or more embodiments of the present disclosure;

FIG. 13 is a diagram showing an intermediate stage, to show a method for manufacturing a semiconductor device according to one or more embodiments of the present disclosure;

FIG. 14 is a diagram showing an intermediate stage, to show a method for manufacturing a semiconductor device according to one or more embodiments of the present disclosure;

FIG. 15 is a diagram showing an intermediate stage, to show a method for manufacturing a semiconductor device according to one or more embodiments of the present disclosure;

FIG. 16 is a diagram showing an intermediate stage, to show a method for manufacturing a semiconductor device according to one or more embodiments of the present disclosure;

FIG. 17 is a diagram showing an intermediate stage, to show a method for manufacturing a semiconductor device according to one or more embodiments of the present disclosure; and

FIG. 18 is a diagram showing an intermediate stage, to show a method for manufacturing a semiconductor device according to one or more embodiments of the present disclosure.

### DETAILED DESCRIPTION

In the present disclosure, the expressions “first”, “second”, and so on are used to describe various devices or components, but it is to be noted that the devices or components are not limited by these expressions. It should be understood that these expressions are only used to distinguish one element or component from another element or component. It goes without saying that the first element or component to be mentioned below may be the second element or component within the technical idea of the present disclosure.

A semiconductor device according to one or more embodiments may include a metal-oxide-semiconductor field effect transistor (MOSFET), and more specifically, a gate-all-round (GAA) transistor and a three-dimensional multi-stack semiconductor device referred to as a multi-bridge channel FET (MBCFET).

Hereinafter, a semiconductor device and a method for manufacturing the same according to one or more embodiments of the present disclosure will be described in detail with reference to drawings.

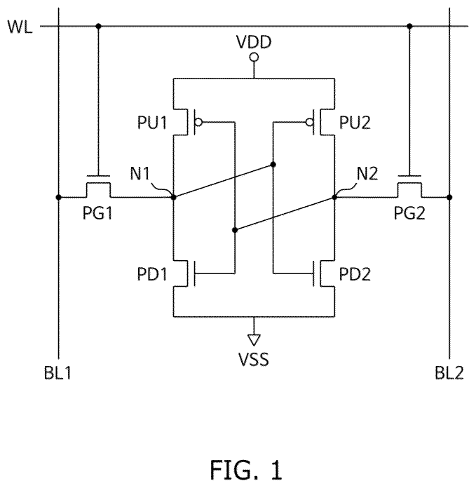

FIG. 1 is a circuit diagram provided to explain a semiconductor device according to one or more embodiments of the present disclosure.

Referring to FIG. 1, a semiconductor device according to one or more embodiments may include at least one cell. For example, the cell may be a static random access memory (SRAM) cell. The cell may include a word line WL, a first bit line BL1, a second bit line BL2, and a plurality of transistors. FIG. 1 may be an example circuit diagram illustrating a cell of a semiconductor device.

The semiconductor device according to one or more embodiments may include a first pass transistor PG1, a second pass transistor PG2, a first pull-up transistor PU1, a second pull-up transistor PU2, a first pull-down transistor PD1, and a second pull-down transistor PD2.

The first pull-up transistor PU1 and the second pull-up transistor PU2 may be P-type metal-oxide-semiconductor field effect transistors (MOSFETs). The first pass transistor PG1, the second pass transistor PG2, the first pull-down transistor PD1, and the second pull-down transistor PD2 may be N-type MOSFETs. The semiconductor device may include six transistors including four NMOS transistors and two PMOS transistors.

The switching electrodes (e.g., gate electrodes) of the first and second pass transistors PG1 and PG2 may be connected to the word line WL. A source pattern of the first pass transistor PG1 may be connected to the first bit line BL1. A source pattern of the second pass transistor PG2 may be connected to the second bit line BL2. A positive voltage VDD may be applied to a source pattern of the first pull-up transistor PU1. A positive voltage VDD may be applied to a source pattern of the second pull-up transistor PU2. A negative voltage VSS may be applied to a source pattern of the first pull-down transistor PD1. A negative voltage VSS may be applied to a source pattern of the second pull-down transistor PD2.

A drain pattern of the first pass transistor PG1, a drain pattern of the first pull-up transistor PU1, and a drain pattern of the first pull-down transistor PD1 may be electrically connected to a first node N1.

A drain pattern of the second pass transistor PG2, a drain pattern of the second pull-up transistor PU2, and a drain pattern of the second pull-down transistor PD2 may be electrically connected to a second node N2.

The switching electrode (e.g., the gate electrode) of the first pull-up transistor PU1 and the switching electrode (e.g., the gate electrode) of the first pull-down transistor PD1 may be electrically connected to the second node N2. The switching electrode (e.g., the gate electrode) of the second pull-up transistor PU2 and the switching electrode (e.g., the gate electrode) of the second pull-down transistor PD2 may be electrically connected to the first node N1. Accordingly, the first and second pull-up transistors PU1 and PU2 and the first and second pull-down transistors PD1 and PD2 may construct a latch circuit including a pair of CMOS inverters.

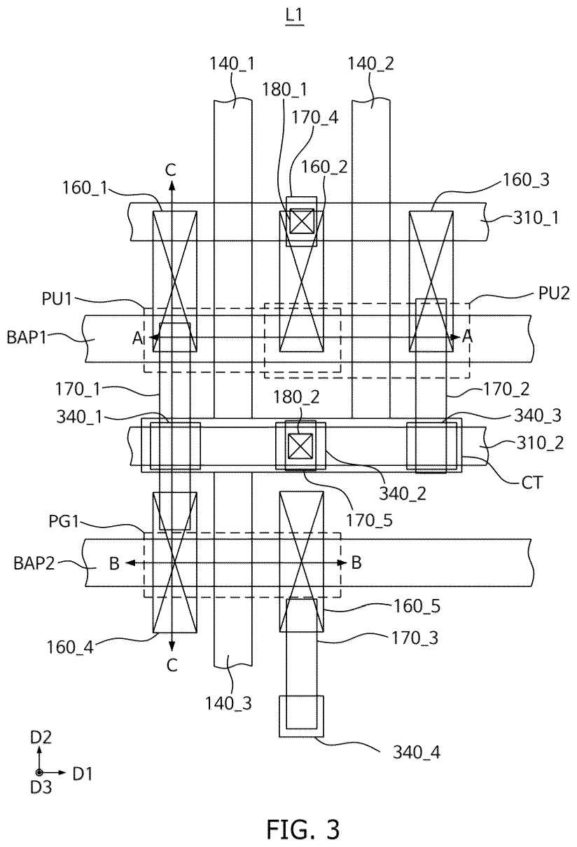

In one or more embodiments, a first power line (e.g., 310_1 of FIG. 3) for applying the positive voltage to the source pattern of the first pull-up transistor PU1 and the second pull-up transistor PU2 may be disposed below the first and second pull-up transistors PU1 and PU2. A second power line (e.g., 310_2 in FIG. 3) for applying the negative voltage to the source patterns of the first pull-down transistor PD1 and the second pull-down transistor PD2 may be disposed below the first and second pull-up transistors PU1 and PU2. This will be described in detail with reference to FIGS. 3 to 7.

In one or more embodiments, the first pull-down transistor PD1 and the second pull-down transistor PD2 may be N-type MOSFETs. The first pass transistor PG1, the second pass transistor PG2, the first pull-up transistor PU1, and the second pull-up transistor PU2 may be P-type MOSFETs. That is, the semiconductor device may include six transistors including four PMOS transistors and two NMOS transistors.

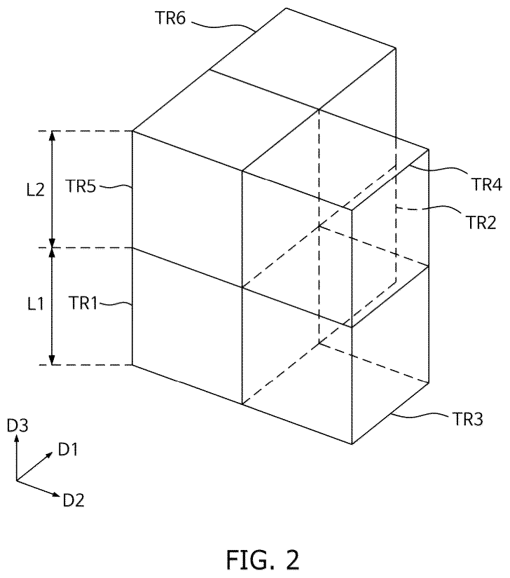

FIG. 2 is a schematic diagram provided to explain a semiconductor device according to one or more embodiments of the present disclosure.

Referring to FIG. 2, the semiconductor device according to one or more embodiments may include first to sixth transistors TR1, TR2, TR3, TR4, TR5, and TR6.

A first transistor group may be disposed at a first level L1. The first transistor group may include the first to third transistors TR1, TR2, and TR3. A second transistor group may be disposed at a second level L2. The second transistor group may include the fourth to sixth transistors TR4, TR5, and TR6. The second level L2 may be disposed above the first level L1. The first level L1 and the second level L2 may overlap each other in a vertical direction D3.

The first transistor TR1 and the fifth transistor TR5 may overlap each other in the vertical direction. The second transistor TR2 and the sixth transistor TR6 may overlap each other in the vertical direction. The third transistor TR3 and the fourth transistor TR4 may overlap each other in the vertical direction.

In one or more embodiments, the first to sixth transistors TR1, TR2, TR3, TR4, TR5, and TR6 may construct a unit cell of the SRAM.

For example, the first transistor TR1 and the second transistor TR2 may be pull-down transistors. The first transistor TR1 and the second transistor TR2 may be N-type MOSFETs. The third transistor TR3 and the fourth transistor TR4 may be pass transistors. Each of the third transistor TR3 and the fourth transistor TR4 may be an N-type MOSFET or a P-type MOSFET. The third transistor TR3 and the fourth transistor TR4 may be MOSFETs of the same conductivity type. The fifth transistor TR5 and the sixth transistor TR6 may be pull-up transistors. The fifth transistor TR5 and the sixth transistor TR6 may be P-type MOSFETs.

As another example, the first transistor TR1 and the second transistor TR2 may be pull-up transistors. The first transistor TR1 and the second transistor TR2 may be P-type MOSFETs. The third transistor TR3 and the fourth transistor TR4 may be pass transistors. Each of the third transistor TR3 and the fourth transistor TR4 may be an N-type MOSFET or a P-type MOSFET. The third transistor TR3 and the fourth transistor TR4 may be MOSFETs of the same conductivity type. The fifth transistor TR5 and the sixth transistor TR6 may be pull-down transistors. The fifth transistor TR5 and the sixth transistor TR6 may be N-type MOSFETs.

When configuring an SRAM cell, six transistors may be disposed in a single SRAM cell. In this case, the size of a single cell of the SRAM may vary depending on how the six transistors are arranged. In the semiconductor device according to one or more embodiments of the present disclosure, the first transistor group disposed at the first level L1 and the second transistor group disposed at the second level L2 overlap each other in the vertical direction. For example, the fifth transistor TR5 vertically overlaps the first transistor TR1, the sixth transistor TR6 vertically overlaps the second transistor TR2, and the fourth transistor TR4 vertically overlaps the third transistor TR3. Using this arrangement of transistors, it is possible to efficiently design the space of the semiconductor device. Accordingly, the size of the unit cell of the SRAM may be reduced, and the degree of integration of the semiconductor device may be improved.

The first to sixth transistors TR1, TR2, TR3, TR4, TR5, and TR6 may have the conductivity types described above. Meanwhile, for convenience of description, in the following drawings, it is assumed that the first transistor TR1 and the second transistor TR2 are P-type MOSFETs, and the third to sixth transistors TR3, TR4, TR5, and TR6 are N-type MOSFETs.

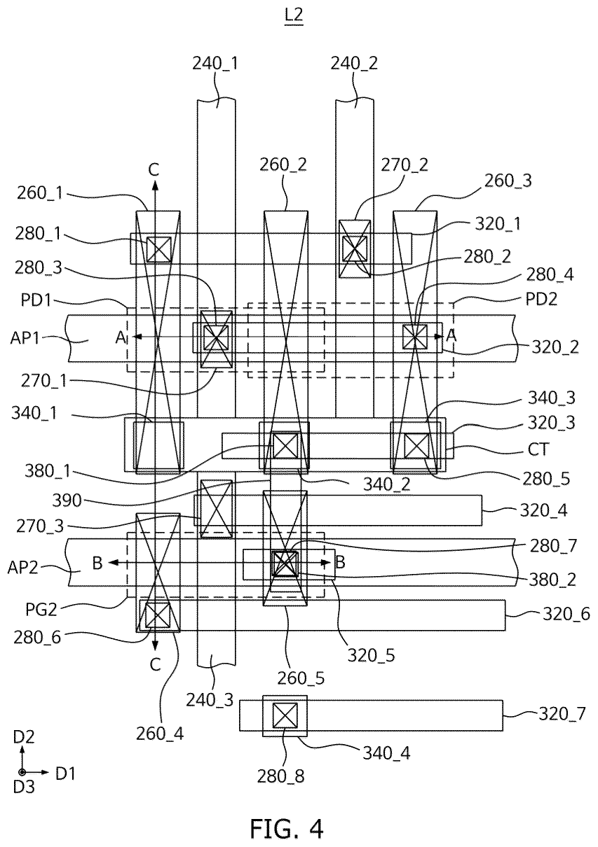

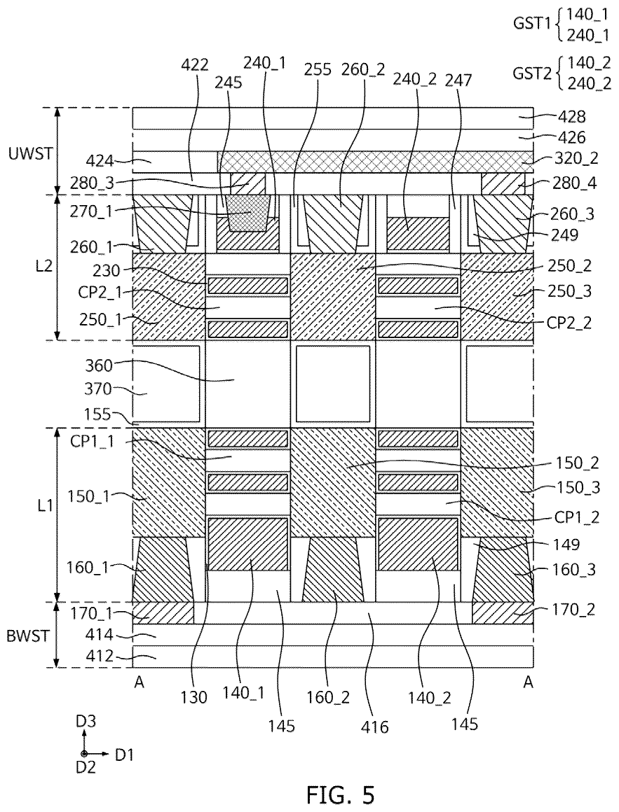

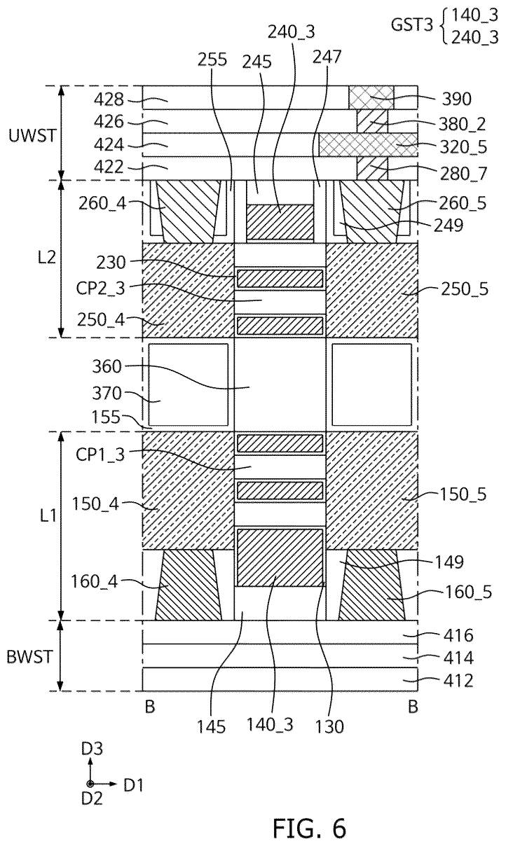

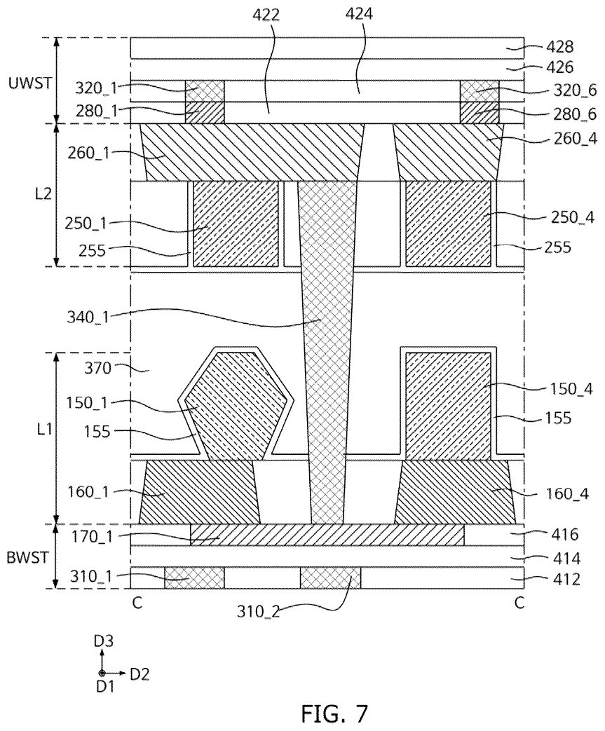

FIGS. 3 and 4 are layout diagrams provided to explain a semiconductor device according to one or more embodiments of the present disclosure. FIG. 5 is a cross-sectional view taken along line A-A of FIGS. 3 and 4. FIG. 6 is a cross-sectional view taken along line B-B of FIGS. 3 and 4. FIG. 7 is a cross-sectional view taken along line C-C of FIGS. 3 and 4. For reference, FIG. 3 is a layout diagram of the first level L1 of the semiconductor device, and FIG. 4 is a layout diagram of the second level L2 of the semiconductor device.

Referring to FIGS. 3 to 7, the semiconductor device according to one or more embodiments may include a first lower active pattern BAP1, a second lower active pattern BAP2, a first upper active pattern AP1, a second upper active pattern AP2, a first gate structure GST1, a second gate structure GST2, a third gate structure GST3, a lower wiring structure BWST, an upper wiring structure UWST, etc.

The first lower active pattern BAP1 may be disposed on the lower wiring structure BWST. The first lower active pattern BAP1 may extend in a first direction D1. The first lower active pattern BAP1 may include a first lower channel pattern CP1_1 and a second lower channel pattern CP1_2. The first lower channel pattern CP1_1 may be disposed to be spaced apart from the second lower channel pattern CP1_2 in the first direction D1.

The first upper active pattern AP1 may be disposed on the first lower active pattern BAP1. The first upper active pattern AP1 may be disposed to be spaced apart from the first lower active pattern BAP1 in a third direction D3. The first upper active pattern AP1 may extend along the first lower active pattern BAP1 in the first direction D1. The first upper active pattern AP1 may include a first upper channel pattern CP2_1 and a second upper channel pattern CP2_2. The first upper channel pattern CP2_1 may be disposed to be spaced apart from the second upper channel pattern CP2_2 in the first direction D1.

The first direction D1 may be a direction in which the first lower active pattern BAP1 extends. A second direction D2 may be a direction perpendicular to the first direction D1. The second direction D2 may be a direction in which the first gate structure GST1 to be described below extends. The third direction D3 may be a direction perpendicular to the first and second directions D1 and D2. The third direction D3 may be a direction perpendicular to an upper surface of the first power line 310_1 to be described below.

The first upper channel pattern CP2_1 may be disposed to be spaced apart from the first lower channel pattern CP1_1 in the third direction D3. The first upper channel pattern CP2_1 may overlap the first lower channel pattern CP1_1 in the third direction D3. A level isolation insulating film 360 may be disposed between the first upper channel pattern CP2_1 and the first lower channel pattern CP1_1. The second upper channel pattern CP2_2 may be disposed to be spaced apart from the second lower channel pattern CP1_2 in the third direction D3. The second upper channel pattern CP2_2 may overlap the second lower channel pattern CP1 2 in the third direction D3. The level isolation insulating film 360 may be disposed between the second upper channel pattern CP2_2 and the second lower channel pattern CP1_2.

The second lower active pattern BAP2 may be disposed on the lower wiring structure BWST. The second lower active pattern BAP2 may extend in the first direction D1. The second lower active pattern BAP2 may be disposed to be spaced apart from the first lower active pattern BAP1 in the second direction D2. The second lower active pattern BAP2 may include a third lower channel pattern CP1_3.

In one or more embodiments, a field insulating film may be disposed between the first lower active pattern BAP1 and the second lower active pattern BAP2.

The second upper active pattern AP2 may be disposed on the second lower active pattern BAP2. The second upper active pattern AP2 may be disposed to be spaced apart from the second lower active pattern BAP2 in the third direction D3. The second upper active pattern AP2 may extend along the second lower active pattern BAP2 in the first direction D1. The second upper active pattern AP2 may include a third upper channel pattern CP2_3.

The third upper channel pattern CP2_3 may be disposed to be spaced apart from the third lower channel pattern CP1_3 in the third direction D3. The third upper channel pattern CP2_3 may overlap the third lower channel pattern CP1_3 in the third direction D3. The level isolation insulating film 360 may be disposed between the third upper channel pattern CP2_3 and the third lower channel pattern CP1_3.

Each of the first to third lower channel patterns CP1_1, CP1_2, and CP1_3 and the first to third upper channel patterns CP2_1, CP2_2, and CP2_3 may include a plurality of sheet patterns. For example, each of the first to third lower channel patterns CP1_1, CP1_2, and CP1_3 and the first to third upper channel patterns CP2_1, CP2_2, and CP2_3 may include two sheet patterns. However, aspects are not limited to the above. Unlike the illustration, each of the first to third lower channel patterns CP1_1, CP1_2, and CP1_3 and the first to third upper channel patterns CP2_1, CP2_2, and CP2_3 may include one or three or more sheet patterns.

In one or more embodiments, the number of sheet patterns of the first to third lower channel patterns CP1_1, CP1_2, and CP1_3 may be different from the number of sheet patterns of the first to third upper channel patterns CP2_1, CP2_2, and CP2_3. For example, the number of sheet patterns of the first to third lower channel patterns CP1_1, CP1_2, and CP1_3 may be three, and the number of sheet patterns of the first to third upper channel patterns CP2_1, CP2_2, and CP2_3 may be two.

The first lower channel pattern CP1_1 may be a channel region of the first pull-up transistor PU1. The second lower channel pattern CP1_2 may be a channel region of the second pull-up transistor PU2. The third lower channel pattern CP1_3 may be a channel region of the first pass transistor PG1. The first upper channel pattern CP2_1 may be a channel region of the first pull-down transistor PD1. The second upper channel pattern CP2_2 may be a channel region of the second pull-down transistor PD2. The third upper channel pattern CP2_3 may be a channel region of the second pass transistor PG2.

Each of the first to third lower channel patterns CP1_1, CP1_2, and CP1_3 and the first to third upper channel patterns CP2_1, CP2_2, and CP2_3 may include one of an element semiconductor material such as silicon (Si) or silicon germanium (SiGe), a group IV-IV compound semiconductor, or a group III-V compound semiconductor.

For example, the group IV-IV compound semiconductor may be a binary compound or a ternary compound including at least two or more of carbon (C), silicon (Si), germanium (Ge), tin (Sn), or a compound doped with a group IV element.

For example, the group III-V compound semiconductor may be one of a binary compound, a ternary compound, or a quaternary compound formed by a combination of at least one of aluminum (Al), gallium (Ga), and indium (In) as a group III element and one of phosphorus (P), arsenic (As), and antimony (Sb) as a group V element.

The first gate structure GST1 may be disposed on the first lower active pattern BAP1 and the first upper active pattern AP1. The first gate structure GST1 may intersect the first lower active pattern BAP1 and the first upper active pattern AP1. The first gate structure GST1 may extend in the second direction D2.

The first gate structure GST1 may include a first lower gate electrode 140_1 and a first upper gate electrode 240 1.

The first lower gate electrode 140_1 may be disposed on the first lower channel pattern CP1_1. The first lower gate electrode 140_1 may surround (or be around) the first lower channel pattern CP1_1. For example, the first lower gate electrode 140_1 may surround (or be around) the sheet patterns of the first lower channel pattern CP1_1.

The first upper gate electrode 240_1 may be disposed above the first lower gate electrode 140_1. The first upper gate electrode 240_1 may be disposed on the first upper channel pattern CP2_1. The first upper gate electrode 240_1 may surround (or be around) the first upper channel pattern CP2_1. For example, the first upper gate electrode 240_1 may surround (or be around) the sheet patterns of the first upper channel pattern CP2_1.

The second gate structure GST2 may be disposed on the first lower active pattern BAP1 and the first upper active pattern AP1. The second gate structure GST2 may intersect the first lower active pattern BAP1 and the first upper active pattern AP1. The second gate structure GST2 may be disposed to be spaced apart from the first gate structure GST1 in the first direction D1. The second gate structure GST2 may extend in the second direction D2.

The second gate structure GST2 may include a second lower gate electrode 140_2 and a second upper gate electrode 240_2.

The second lower gate electrode 140_2 may be disposed on the second lower channel pattern CP1_2. The second lower gate electrode 140_2 may surround (or be around) the second lower channel pattern CP1_2. For example, the second lower gate electrode 140_2 may surround (or be around) the sheet patterns of the second lower channel pattern CP1_2.

The second upper gate electrode 240_2 may be disposed above the second lower gate electrode 140_2. The second upper gate electrode 240_2 may be disposed on the second upper channel pattern CP2_2. The second upper gate electrode 240_2 may surround (or be around) the second upper channel pattern CP2_2. For example, the second upper gate electrode 240_2 may surround (or be around) the sheet patterns of the second upper channel pattern CP2_2.

The third gate structure GST3 may be disposed on the second lower active pattern BAP2 and the second upper active pattern AP2. The third gate structure GST3 may intersect the second lower active pattern BAP2 and the second upper active pattern AP2. The third gate structure GST3 may extend in the second direction D2. The third gate structure GST3 may be disposed to be spaced apart from the first gate structure GST1 in the second direction D2. The third gate structure GST3 may overlap the first gate structure GST1 in the second direction D2.

The third gate structure GST3 may include a third lower gate electrode 140_3 and a third upper gate electrode 240_3.

The third lower gate electrode 140_3 may be disposed on the third lower channel pattern CP1_3. The third lower gate electrode 140_3 may surround (or be around) the third lower channel pattern CP1_3. For example, the third lower gate electrode 140_3 may surround (or be around) the sheet patterns of the third lower channel pattern CP1_3.

The third upper gate electrode 240_3 may be disposed above the third lower gate electrode 140_3. The third upper gate electrode 240_3 may be disposed on the third upper channel pattern CP2_3. The third upper gate electrode 240_3 may surround (or be around) the third upper channel pattern CP2_3. For example, the third upper gate electrode 240_3 may surround (or be around) the sheet patterns of the third upper channel pattern CP2_3.

The first lower gate electrode 140_1 and the first upper gate electrode 240_1 may be electrically connected to each other. The level isolation insulating film 360 may separate the first lower gate electrode 140_1 and the first upper gate electrode 240_1. The first lower gate electrode 140_1 and the first upper gate electrode 240_1 may be electrically connected to each other through conductive wiring. In another aspect, the first lower gate electrode 140_1 and the first upper gate electrode 240_1 may be in direct contact with each other.

The second lower gate electrode 140_2 and the second upper gate electrode 240_2 may be electrically connected to each other. The level isolation insulating film 360 may separate the second lower gate electrode 140_2 and the second upper gate electrode 240_2. The second lower gate electrode 140_2 and the second upper gate electrode 240_2 may be electrically connected to each other through conductive wiring. In another aspect, the second lower gate electrode 140_2 and the second upper gate electrode 240_2 may be in direct contact with each other.

The third lower gate electrode 140_3 and the third upper gate electrode 240_3 may be electrically connected to each other. In one or more embodiments, the third lower gate electrode 140_3 and the third upper gate electrode 240_3 may be in direct contact with each other.

The first gate structure GST1 may be electrically connected to the drain pattern of the second pull-up transistor PU2, the drain pattern of the second pull-down transistor PD2, and the drain pattern of the second pass transistor PG2, respectively.

The second gate structure GST2 may be electrically connected to the drain pattern of the first pull-up transistor PU1, the drain pattern of the first pull-down transistor PD1, and the drain pattern of the first pass transistor PG1, respectively.

The third gate structure GST3 may be electrically connected to a fourth upper line wiring 320_4. Specifically, a third upper gate contact 270_3 may be disposed on an upper surface of the third upper gate electrode 240_3. The fourth upper line wiring 320_4 may be disposed on an upper surface of the third upper gate contact 270_3. For example, the fourth upper line wiring 320_4 may be the word line WL of FIG. 1.

Each of the first to third lower gate electrodes 140_1, 140_2, and 140_3 and the first to third upper gate electrodes 240_1, 240_2, and 240_3 may include at least one of a metal, a metal alloy, a conductive metal nitride, a metal silicide, a doped semiconductor material, a conductive metal oxide, and a conductive metal oxynitride. Each of the first to third lower gate electrodes 140_1, 140_2, 140_3, and the first to third upper gate electrodes 240_1, 240_2, and 240_3 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but is not limited thereto.

Although it is illustrated that each of the first to third lower gate electrodes 140_1, 140_2, and 140_3 and the first to third upper gate electrodes 240_1, 240_2, and 240_3 is a single film, aspects are not limited thereto. For example, each of the first to third lower gate electrodes 140_1, 140_2, and 140_3 and the first to third upper gate electrodes 240_1, 240_2, and 240_3 may include a work function control film that adjusts a work function and a filling conductive film that fills a space formed by the work function control film. For example, the work function control film may include at least one of TiN, TaN, TiC, TaC, TiAlC, and a combination thereof. For example, the filling conductive layer may include W or Al.

In one or more embodiments, some of the first to third lower gate electrodes 140_1, 140_2, and 140_3 and the first to third upper gate electrodes 240_1, 240_2, and 240_3 may include a work function control film of a different conductivity type. For example, the work function control film of the first lower gate electrode 140_1 and the second lower gate electrode 140_2 may include a P-type work function control film, and the work function control film of the third lower gate electrode 140_3 and the first to third upper gate electrodes 240_1, 240_2, and 240_3 may include an N-type work function control film.

A gate isolation pattern CT may be disposed between the third gate structure GST3 and the first gate structure GST1. The gate isolation pattern CT may extend in the first direction D1. A width of the gate isolation pattern CT in the second direction D2 may be greater than a width of a first through via 340_1 (to be described below) in the second direction D2. The first through via 340_1, a second through via 340_2, and a third through via 340_3 may be disposed in the gate isolation pattern CT.

A lower gate insulating film 130 may be disposed on the first lower gate electrode 140_1, the second lower gate electrode 140_2, and the third lower gate electrode 140_3. The description of the lower gate insulating film 130 disposed on the first lower gate electrode 140_1 may be similar to the description of the lower gate insulating film 130 disposed on the second and third lower gate electrodes 140_2 and 140_3. The lower gate insulating film 130 will be described below mainly with reference to the first lower gate electrode 140_1.

The lower gate insulating film 130 may be disposed between the first lower gate electrode 140_1 and the first lower channel pattern CP1_1 and between the lower source/drain patterns (e.g., between a first lower source/drain pattern 150_1 and a second lower source/drain pattern 150_2) adjacent to the first lower gate electrode 140_1, respectively. Although it is illustrated that the lower gate insulating film 130 is a single layer, aspects are not limited thereto. Unlike the illustration, the lower gate insulating film 130 may include a plurality of films. The lower gate insulating film 130 may include a high-k insulating film and an interfacial insulating film.

An upper gate insulating film 230 may be disposed on the first upper gate electrode 240_1, the second upper gate electrode 240_2, and the third upper gate electrode 240_3. The description of the upper gate insulating film 230 disposed on the first upper gate electrode 240_1 may be similar to the description of the upper gate insulating film 230 disposed on the second and third upper gate electrodes 240_2 and 240_3. Hereinafter, the upper gate insulating film 230 will be described mainly with reference to the first upper gate electrode 240_1.

The upper gate insulating film 230 may be disposed between the first upper gate electrode 240_1 and the first upper channel pattern CP2_1 and between the lower source/drain patterns (e.g., a first upper source/drain pattern 250_1 and a second upper source/drain pattern 250_2) adjacent to the first upper gate electrode 240_1, respectively. Although it is illustrated that the upper gate insulating film 230 is a single layer, aspects are not limited thereto. Unlike the illustration, the upper gate insulating film 230 may include a plurality of films. The upper gate insulating film 230 may include a high-k insulating film and an interfacial insulating film.

For example, each of the lower gate insulating film 130 and the upper gate insulating film 230 may include a high-k material having a dielectric constant greater than that of silicon oxide, silicon oxynitride, silicon nitride, or silicon oxide. For example, the high-k material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

A lower gate capping pattern 145 may be disposed on a lower surface of the first lower gate electrode 140_1, a lower surface of the second lower gate electrode 140_2, and a lower surface of the third lower gate electrode 140_3, respectively. The lower gate capping pattern 145 may cover the lower surface of the first lower gate electrode 140_1, the lower surface of the second lower gate electrode 140_2 and the lower surface of the third lower gate electrode 140_3, respectively. A lower surface of the lower gate capping pattern 145 may be disposed flush with a lower surface of a lower insulating film 149. However, aspects are not limited to the above.

The description of an upper gate capping pattern 245 disposed on the first upper gate electrode 240_1 may be similar to that of the upper gate capping pattern 245 disposed on the second and third upper gate electrodes 240_2 and 240_3. Hereinafter, the upper gate capping pattern 245 will be described with reference to the upper gate capping pattern 245 disposed on the first upper gate electrode 240_1.

The upper gate capping pattern 245 may be disposed on an upper surface of the first upper gate electrode 240_1. The upper gate capping pattern 245 may cover the upper surface of the first upper gate electrode 240_1. The upper gate capping pattern 245 may be disposed between upper gate spacers 247. A side surface of the upper gate capping pattern 245 may be in contact with the upper gate spacer 247. The upper surface of the upper gate capping pattern 245 may be disposed flush with an upper surface of an upper insulating film 249. However, aspects are not limited to the above.

For example, each of the lower gate capping pattern 145 and the upper gate capping pattern 245 may include at least one of silicon nitride (SiN), silicon oxynitride (SiON), silicon carbon nitride (SiCN), silicon oxycarbonitride (SiOCN), and a combination thereof. The lower gate capping pattern 145 may include a material having etch selectivity with respect to the lower insulating film 149. The upper gate capping pattern 245 may include a material having etch selectivity with respect to the upper insulating film 249.

The description of the upper gate spacer 247 disposed on the first upper gate electrode 240_1 may be similar to the description of the upper gate spacer 247 disposed on the second and third upper gate electrodes 240_2 and 240_3. Hereinafter, the upper gate spacer 247 will be described mainly with reference to the upper gate spacer 247 disposed on the first upper gate electrode 240_1.

The upper gate spacer 247 may be disposed on a side surface of the first upper gate electrode 240_1 and a side surface of the upper gate capping pattern 245. For example, the upper gate spacer 247 may extend along the side surface of the first upper gate electrode 240_1, that is, the side surface of the first upper gate electrodes 240_1 disposed above the first upper channel pattern CP2_1 and the side surface of the upper gate capping pattern 245.

For example, the upper gate spacer 247 may include at least one of silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), and a combination thereof. Although it is illustrated that the upper gate spacer 247 is a single layer, it is only for convenience of description, and aspects are not limited thereto.

The first to third lower source/drain patterns 150_1, 150_2, and 150_3 may be disposed on the first lower active pattern BAP1.

The first lower source/drain pattern 150_1 may be disposed on one side of the first lower channel pattern CP1_1. The second lower source/drain pattern 150_2 may be disposed on the other side of the first lower channel pattern CP1_1. The first lower source/drain pattern 150_1 and the second lower source/drain pattern 150_2 may face each other with respect to the first lower channel pattern CP1_1 in the first direction D1.

The second lower source/drain pattern 150_2 may be disposed on one side of the second lower channel pattern CP1_2. The third lower source/drain pattern 150_3 may be disposed on the other side of the second lower channel pattern CP1_2. The second lower source/drain pattern 150_2 and the third lower source/drain pattern 150_3 may face each other with respect to the second lower channel pattern CP1_2 in the first direction D1.

In one or more embodiments, the first lower source/drain pattern 150_1 may be a drain pattern of the first pull-up transistor PU1. The second lower source/drain pattern 150_2 may be a source pattern of the first pull-up transistor PU1 and may also be a source pattern of the second pull-up transistor PU2. That is, the first pull-up transistor PU1 and the second pull-up transistor PU2 may share the source pattern. The third lower source/drain pattern 150_3 may be a drain pattern of the second pull-up transistor PU2.

The fourth and fifth lower source/drain patterns 150_4 and 150_5 may be disposed on the second lower active pattern BAP2.

The fourth lower source/drain pattern 150_4 may be disposed on one side of the third lower channel pattern CP1_3. The fifth lower source/drain pattern 150_5 may be disposed on the other side of the third lower channel pattern CP1_3. The fourth lower source/drain pattern 150_4 and the fifth lower source/drain pattern 150_5 may face each other with respect to the third lower channel pattern CP1_3 in the first direction D1.

In one or more embodiments, the fourth lower source/drain pattern 150_4 may be a drain pattern of the first pass transistor PG1. The fifth lower source/drain pattern 150_5 may be a source pattern of the first pass transistor PG1.

Each of the first to fifth lower source/drain patterns 150_1, 150_2, 150_3, 150_4, and 150_5 may include an epitaxial pattern. Each of the first to fifth lower source/drain patterns 150_1, 150_2, 150_3, 150_4, and 150_5 may include a semiconductor material. For example, each of the first to fifth lower source/drain patterns 150_1, 150_2, 150_3, 150_4, and 150_5 may include an element semiconductor material such as silicon (Si) or germanium (Ge). In addition, for example, each of the first to fifth lower source/drain patterns 150_1, 150_2, 150_3, 150_4, and 150_5 may include a binary compound or a ternary compound including at least two or more of carbon (C), silicon (Si), germanium (Ge), tin (Sn), or a compound doped with a group IV element. For example, each of the first to fifth lower source/drain patterns 150_1, 150_2, 150_3, 150_4, and 150_5 may include silicon (Si), silicon-germanium (SiGe), germanium (Ge), silicon carbide (SiC), etc., but aspects are not limited thereto.

The first to third upper source/drain patterns 250_1, 250_2, and 250_3 may be disposed on the first upper active pattern AP1. Each of the first to third upper source/drain patterns 250_1, 250_2, and 250_3 may be disposed to be spaced apart from each of the first to third lower source/drain patterns 150_1, 150_2, and 150_3 in the third direction D3.

The first upper source/drain pattern 250_1 may be disposed on one side of the first upper channel pattern CP2_1. The second upper source/drain pattern 250_2 may be disposed on the other side of the first upper channel pattern CP2_1. The first upper source/drain pattern 250_1 and the second upper source/drain pattern 250_2 may face each other with respect to the first upper channel pattern CP2_1 in the first direction DI.

The second upper source/drain pattern 250_2 may be disposed on one side of the second upper channel pattern CP2_2. The third upper source/drain pattern 250_3 may be disposed on the other side of the second upper channel pattern CP2_2. The second upper source/drain pattern 250_2 and the third upper source/drain pattern 250_3 may face each other with respect to the second upper channel pattern CP2_2 in the first direction D1.

In one or more embodiments, the first upper source/drain pattern 250_1 may be a drain pattern of the first pull-down transistor PD1. The second upper source/drain pattern 250_2 may be a source pattern of the first pull-down transistor PD1 and may also be a source pattern of the second pull-down transistor PD2. That is, the first pull-down transistor PD1 and the second pull-down transistor PD2 may share the source pattern. The third upper source/drain pattern 250_3 may be a drain pattern of the second pull-down transistor PD2.

Fourth and fifth upper source/drain patterns 250_4 and 250_5 may be disposed on the second upper active pattern AP2. Each of the fourth and fifth upper source/drain patterns 250_4 and 250_5 may be spaced apart from each of the fourth and fifth lower source/drain patterns 150_4 and 150_5 in the third direction D3.

The fourth upper source/drain pattern 250_4 may be disposed on one side of the third upper channel pattern CP2_3. The fifth upper source/drain pattern 250_5 may be disposed on the other side of the third upper channel pattern CP2_3. The fourth upper source/drain pattern 250_4 and the fifth upper source/drain pattern 250_5 may face each other with respect to the third upper channel pattern CP2_3 in the first direction D1.

In one or more embodiments, the fourth upper source/drain pattern 250_4 may be a source pattern of the second pass transistor PG2. The fifth upper source/drain pattern 250_5 may be a drain pattern of the second pass transistor PG2.

Each of the first to fifth upper source/drain patterns 250_1, 250_2, 250_3, 250_4, and 250_5 may include an epitaxial pattern. Each of the first to fifth upper source/drain patterns 250_1, 250_2, 250_3, 250_4, and 250_5 may include a semiconductor material. The description of the material of each of the first to fifth upper source/drain patterns 250_1, 250_2, 250_3, 250_4, and 250_5 may be the same as the description of the first lower source/drain pattern 150_1.

The first to third lower source/drain patterns 150_1, 150_2, and 150_3 may have a first conductivity type. The fourth and fifth lower source/drain patterns 150_4 and 150_5 and the first to fifth upper source/drain patterns 250_1, 250_2, 250_3, 250_4, and 250_5 may have a second conductivity type. The second conductivity type may be different from the first conductivity type. In one or more embodiments, the first conductivity type may be a p-type and the second conductivity type may be an n-type. However, aspects are not limited to the above.

First to fifth lower source/drain contacts 160_1, 160_2, 160_3, 160_4, and 160_5 may be disposed on each of the first to fifth lower source/drain patterns 150_1, 150_2, 150_3, 150_4, and 150_5. Each of the first to fifth lower source/drain contacts 160_1, 160_2, 160_3, 160_4, and 160_5 may be electrically connected to the first to fifth lower source/drain patterns 150_1, 150_2, 150_3, 150_4, and 150_5. Each of the first to fifth lower source/drain contacts 160_1, 160_2, 160_3, 160_4, and 160_5 may extend through the lower insulating film 149.

For example, the first lower source/drain contact 160_1 may be disposed on a lower surface of the first lower source/drain pattern 150_1. Although it is illustrated that the lower surface of the first lower source/drain pattern 150_1 and the upper surface of the first lower source/drain contact 160_1 are flush with each other, aspects are not limited thereto. For example, a portion of the first lower source/drain contact 160_1 may extend through the lower surface of the first lower source/drain pattern 150_1.

First to fifth upper source/drain contacts 260_1, 260_2, 260_3, 260_4, and 260_5 may be disposed on each of the first to fifth upper source/drain patterns 250_1, 250_2, 250_3, 250_4, and 250_5. Each of the first to fifth upper source/drain contacts 260_1, 260_2, 260_3, 260_4, and 260_5 may be electrically connected to the first to fifth upper source/drain patterns 250_1, 250_2, 250_3, 250_4, and 250_5. The first to fifth upper source/drain contacts 260_1, 260_2, 260_3, 260_4, and 260_5 may extend through the upper insulating film 249 and an upper etching stop film 255.

For example, the first upper source/drain contact 260_1 may be disposed on an upper surface of the first upper source/drain pattern 250_1. Although it is illustrated that the upper surface of the first upper source/drain pattern 250_1 and the lower surface of the first upper source/drain contact 260_1 are flush with each other, aspects are not limited thereto. For example, a portion of the first upper source/drain contact 260_1 may extend through the upper surface of the first upper source/drain pattern 250_1.

A lower etching stop film 155 may be disposed on the first to fifth lower source/drain patterns 150_1, 150_2, 150_3, 150_4, and 150_5. The upper etching stop film 255 may be disposed on the first to fifth upper source/drain patterns 250_1, 250_2, 250_3, 250_4, and 250_5. For example, each of the lower etching stop film 155 and the upper etching stop film 255 may include at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), and a combination thereof.

An intermediate insulating film 370 may be disposed between the lower source/drain patterns 150_1, 150_2, 150_3, 150_4, and 150_5 and the upper source/drain patterns 250_1, 250_2, 250_3, 250_4, and 250_4. For example, the intermediate insulating film 370 may include at least one of silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

The first lower active pattern BAP1 and the second lower active pattern BAP2 may be disposed at the first level L1. The first upper active pattern AP1 and the second upper active pattern AP2 may be disposed on the second level L2. The lower wiring structure BWST may be disposed below the first level L1. The upper wiring structure UWST may be disposed above the second level L2.

The lower wiring structure BWST may include first to third lower wiring insulating films 412, 414, and 416, and wires disposed in the first to third lower wiring insulating films 412, 414, and 416. For example, the first power line 310_1 and a second power line 310_2 may be disposed in the first lower wiring insulating film 412. A first lower via 180 1 and a second lower via 180_2 may be disposed in the second lower wiring insulating film 414. First to fifth lower connection wirings 170_1, 170_2, 170_3, 170_4, and 170_5 may be disposed in the third lower insulating film 416.

The upper wiring structure UWST may include first to fourth upper wiring insulating films 422, 424, 426, and 428, and wires disposed in the first to fourth upper wiring insulating films 422, 424, 426, and 428. For example, first to eighth upper vias 280_1, 280_2, 280_3, 280_4, 280_5, 280_6, 280_7, and 280_8 may be disposed in the first upper wiring insulating film 422. First to seventh upper line wirings 320_1, 320_2, 320_3, 320_4, 320_5, 320_6, and 320_7 may be disposed in the second upper line insulating film 424. A ninth upper via 380_1 and a tenth upper via 380_2 may be disposed in the third upper wiring insulating film 426. An upper connection wiring 390 may be disposed in the fourth upper wiring insulating film 428.

For example, each of the first to third lower wiring insulating films 412, 414, and 416 and the first to fourth upper wiring insulating films 422, 424, 426, and 428 may include at least one of silicon oxide, silicon nitride, silicon oxynitride, and a low-k material.

In one or more embodiments, the transistors (e.g., PU1, PU2, PG1) disposed at the first level L1 may be electrically connected to the transistors (e.g., PD1, PD2, PG2) disposed at the second level L2 through the lower wiring structure BSWT and the upper wiring structure UWST. Hereinafter, the connection relationship between the above components will be described in detail.

The first lower source/drain pattern 150_1 may be electrically connected to the first upper source/drain pattern 250_1. The first upper source/drain contact 260_1 may be disposed on an upper surface of the first upper source/drain pattern 250_1. The first lower source/drain contact 160_1 may be disposed on the lower surface of the first lower source/drain pattern 150_1. The first lower connection wiring 170_1 may be disposed on a lower surface of the first lower source/drain contact 160_1. The first lower connection wiring 170_1 may extend in the second direction D2. The first through via 340_1 may be disposed on the upper surface of a first lower connection wiring 170_1. The first through via 340_1 may extend in the third direction D3. The first upper source/drain contact 260_1 may be disposed on an upper surface of the first through via 340_1. That is, the first lower source/drain pattern 150_1 may be electrically connected to the first upper source/drain pattern 250_1 through the first lower source/drain contact 160_1, the first lower connection wiring 170_1, the first through via 340_1, and the first upper source/drain contact 260_1.

The first lower source/drain pattern 150_1 may be electrically connected to the fourth lower source/drain pattern 150_4. The first lower source/drain contact 160_1 may be disposed on the lower surface of the first lower source/drain pattern 150_1. The fourth lower source/drain contact 160_4 may be disposed on a lower surface of the fourth lower source/drain pattern 150_4. One end of the first lower connection wiring 170_1 may be in contact with the first lower source/drain contact 160_1, and the other end thereof may be in contact with the fourth lower source/drain contact 160_4. That is, the first lower source/drain pattern 150_1 may be electrically connected to the fourth lower source/drain pattern 150_4 through the first lower source/drain contact 160_1, the first lower connection wiring 170_1, and the fourth lower source/drain contact 160_4.

The first upper source/drain pattern 250_1 may be electrically connected to the second gate structure GST2. The first upper source/drain contact 260_1 may be disposed on the upper surface of the first upper source/drain pattern 250_1. The first upper via 280_1 may be disposed on the upper surface of the first upper source/drain contact 260_1. The first upper line wiring 320_1 may be disposed on the upper surface of the first upper via 280_1. The first upper line wiring 320_1 may extend in the first direction D1. The second upper via 280_2 may be disposed on the lower surface of the first upper line wiring 320_1. A second upper gate contact 270_2 may be disposed on a lower surface of the second upper via 280_2. The second upper gate electrode 240_2 may be disposed on a lower surface of the second upper gate contact 270_2. That is, the first upper source/drain pattern 250_1 may be electrically connected to the second gate structure GST2 through the first upper source/drain contact 260_1, the first upper via 280_1, the first upper line wiring 320_1, the second upper via 280_2, and the second upper gate contact 270_2.

The second lower source/drain pattern 150_2 may be electrically connected to the first power line 310_1. The second lower source/drain contact 160_2 may be disposed on a lower surface of the second lower source/drain pattern 150_2. The fourth lower connection wiring 170_4 may be disposed on a lower surface of the second lower source/drain contact 160_2. The first lower via 180_1 may be disposed on a lower surface of the fourth lower connection wiring 170_4. A lower surface of the first lower via 180_1 may be in contact with the first power line 310_1. That is, the second lower source/drain pattern 150_2 may be electrically connected to the first power line 310_1 through the second lower source/drain contact 160_2, the fourth lower connection wiring 170_4, and the first lower via 180_1.

The second upper source/drain pattern 250_2 may be electrically connected to the second power line 310_2. The second upper source/drain contact 260_2 may be disposed on an upper surface of the second upper source/drain pattern 250_2. The second through via 340_2 may be disposed on a lower surface of the second upper source/drain contact 260_2. The second through via 340_2 may extend in the third direction D3. The fifth lower connection wiring 170_5 may be disposed on a lower surface of the second through via 340_2. The second lower via 180_2 may be disposed on a lower surface of the fifth lower connection wiring 170_5. The second power line 310_2 may be disposed on a lower surface of the second lower via 180_2. That is, the second upper source/drain pattern 250_2 may be electrically connected to the second power line 310_2 through the second upper source/drain contact 260_2, the second through via 340_2, the fifth lower connection wiring 170_5, and the second lower via 180_2.

In one or more embodiments, a positive voltage (e.g., VDD of FIG. 1) may be applied to the second lower source/drain pattern 150_2 through the first power line 310_1. A negative voltage (e.g., VSS of FIG. 1) may be applied onto the second upper source/drain pattern 250_2 through the second power line 310_2.

The third lower source/drain pattern 150_3 may be electrically connected to the third upper source/drain pattern 250_3. The third lower source/drain contact 160_3 may be disposed on a lower surface of the third lower source/drain pattern 150_3. The second lower connection wiring 170_2 may be disposed on a lower surface of the third lower source/drain contact 160_3. The second lower connection wiring 170_2 may extend in the second direction D2. The second lower connection wiring 170_2 may not be in contact with the second power line 310_2. The third through via 340_3 may be disposed on an upper surface of the second lower connection wiring 170_2. The third through via 340_3 may extend in the third direction D3. The third upper source/drain contact 260_3 may be disposed on an upper surface of the third through via 340_3. That is, the third lower source/drain pattern 150_3 may be electrically connected to the third upper source/drain pattern 250_3 through the third lower source/drain contact 160_3, the second lower connection wiring 170_2, the third through via 340_3, and the third upper source/drain contact 260_3.

The third upper source/drain pattern 250_3 may be electrically connected to the fifth upper source/drain pattern 250_5. The third upper source/drain contact 260_3 may be disposed on an upper surface of the third upper source/drain pattern 250_3. The fifth upper via 280_5 may be disposed on an upper surface of the third upper source/drain contact 260_3. The third upper line wiring 320_3 may be disposed on an upper surface of the fifth upper via 280_5. The third upper line wiring 320_3 may extend in the first direction D1. The ninth upper via 380_1 may be disposed on an upper surface of the third upper line wiring 320_3. The upper connection wiring 390 may be disposed on an upper surface of the ninth upper via 380_1. The upper connection wiring 390 may extend in the second direction D2. The tenth upper via 380_2, the fifth upper line wiring 320_5, and the seventh upper via 280_7 may be sequentially disposed on a lower surface of the upper connection wiring 390. The fifth upper source/drain contact 260_5 may be disposed on a lower surface of the seventh upper via 280_7. That is, the third upper source/drain pattern 250_3 may be electrically connected to the fifth upper source/drain pattern 250_5 through the third upper source/drain contact 260_3, the fifth upper via 280_5, the third upper line wiring 320_3, the ninth upper via 380_1, the upper connection wiring 390, the tenth upper via 380_2, the fifth upper line wiring 320_5, the seventh upper via 280_7, and the fifth upper source/drain contact 260_5.

The first to eighth upper vias 280_1, 280_2, 280_3, 280_4, 280_5, 280_6, 280_7, and 280_8 may be disposed at the same level, and the ninth upper via 380_1 and the tenth upper via 380_2 may be disposed at the same level. The ninth upper via 380_1 may be disposed above the first upper via 280_1.

The third upper source/drain pattern 250_3 may be electrically connected to the first gate structure GST1. The third upper source/drain contact 260_3 may be disposed on the upper surface of the third upper source/drain pattern 250_3. The fourth upper via 280_4 may be disposed on the upper surface of the third upper source/drain contact 260_3. The second upper line wiring 320_2 may be disposed on an upper surface of the fourth upper via 280_4. The second upper line wiring 320_2 may extend in the first direction D1. The third upper via 280_3 may be disposed on a lower surface of the second upper line wiring 320_2. A first upper gate contact 270_1 may be disposed on a lower surface of the third upper via 280_3. The first upper gate contact 270_1 may be disposed on the upper surface of the first upper gate electrode 240_1. That is, the third upper source/drain pattern 250_3 may be electrically connected to the first gate structure GST1 through the third upper source/drain contact 260_3, the fourth upper via 280_4, the second upper line wiring 320_2, the third upper via 280_3, and the first upper gate contact 270_1.

The fifth lower source/drain pattern 150_5 may be electrically connected to the seventh upper line wiring 320_7. The fifth lower source/drain contact 160_5 may be disposed on a lower surface of the fifth lower source/drain pattern 150_5. The third lower connection wiring 170_3 may be disposed on a lower surface of the fifth lower source/drain contact 160_5. The third lower connection wiring 170_3 may extend in the second direction D2. A fourth through via 340_4 may be disposed on an upper surface of the third lower connection wiring 170_3. The fourth through via 340_4 may extend in the third direction D3. The eighth upper via 280_8 may be disposed on an upper surface of the fourth through via 340_4. The seventh upper line wiring 320_7 may be disposed on an upper surface of the eighth upper via 280_8. That is, the fifth lower source/drain pattern 150_5 may be electrically connected to the seventh upper line wiring 320_7 through the fifth lower source/drain contact 160_5, the third lower connection wiring 170_3, the fourth through via 340_4, and the eighth upper via 280_8. For example, the seventh upper line wiring 320_7 may be the first bit line BL1 of FIG. 1.

The fourth upper source/drain pattern 250_4 may be electrically connected to the sixth upper line wiring 320_6. The fourth upper source/drain contact 260_4 may be disposed on an upper surface of the fourth upper source/drain pattern 250_4. The sixth upper via 280_6 may be disposed on an upper surface of the fourth upper source/drain contact 260_4. The sixth upper line wiring 320_6 may be disposed on the sixth upper via 280_6. That is, the fourth upper source/drain pattern 250_4 may be electrically connected to the sixth upper line wiring 320_6 through the fourth upper source/drain contact 260_4 and the sixth upper via 280_6. For example, the sixth upper line wiring 320_6 may be the second bit line BL2 of FIG. 1.

In one or more embodiments, a substrate may be further disposed between the first level L1 and the lower wiring structure BWST. The substrate may be a bulk silicon or a silicon-on-insulator (SOI). The substrate 100 may include silicon germanium (SiGe), silicon germanium on insulator (SGOI), indium antimony, lead tellurium compound, indium arsenic, indium phosphide, gallium arsenic, or gallium antimony, but aspects are not limited thereto. The first to fifth lower source/drain contacts 160_1, 160_2, 160_3, 160_4, and 160_5 may extend through the substrate and connected to the lower wiring structure BWST.

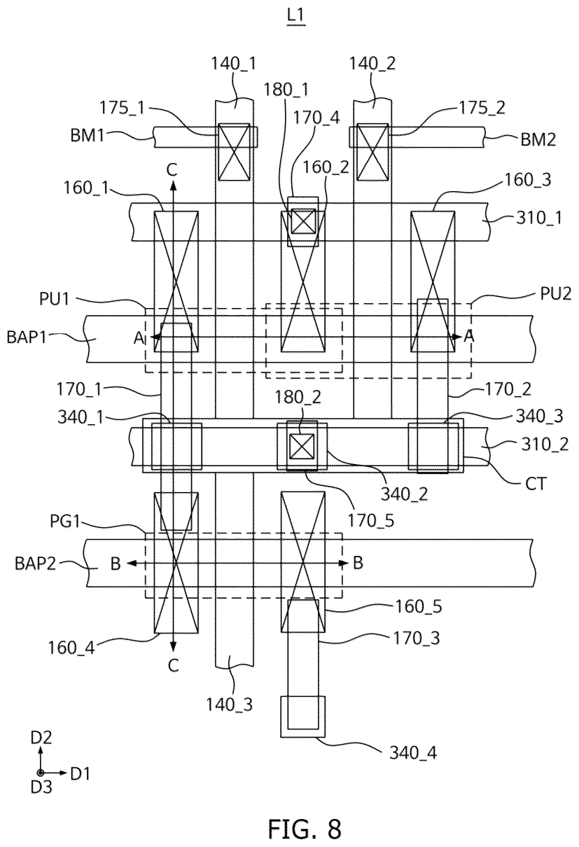

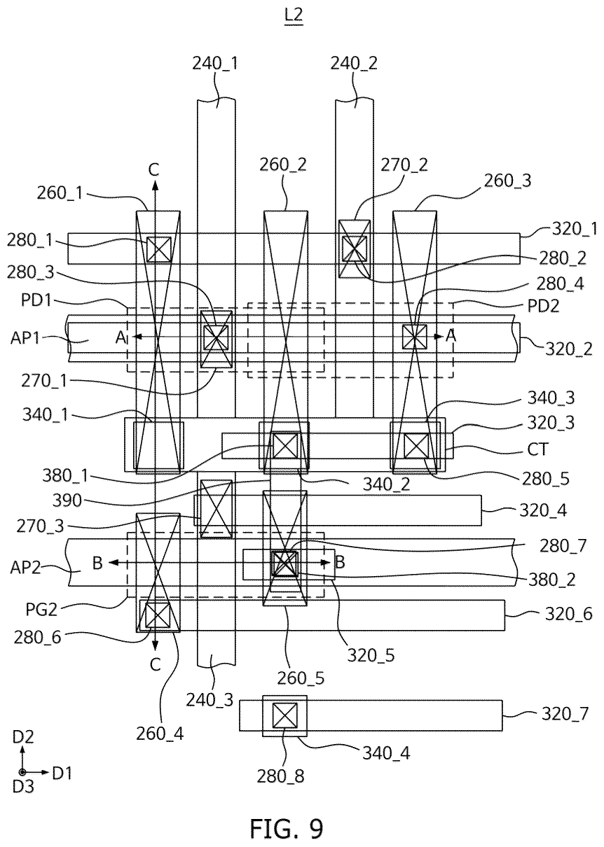

FIGS. 8 and 9 are layout diagrams provided to explain a semiconductor device according to one or more embodiments of the present disclosure. For convenience of description, different configurations from those described in FIGS. 3 to 7 will be mainly described.

Referring to FIGS. 8 and 9, the semiconductor device according to one or more embodiments may further include a first lower gate contact 175_1, a second lower gate contact 175_2, a first lower line wiring BM1, and a second lower line wiring BM2.

The first lower gate contact 175_1 may be disposed on the lower surface of the first lower gate electrode 140_1. The first lower line wiring BM1 may be disposed on a lower surface of the first lower gate contact 175_1. The first lower line wiring BM1 may extend in the first direction D1.

The first lower gate electrode 140_1 and the first upper gate electrode 240_1 may not be in direct contact with each other. The first lower gate electrode 140_1 may be electrically connected to the first upper gate electrode 240_1. For example, the first lower line wiring BMI may be electrically connected to the second upper line wiring 320_2. A line wiring, a through via, etc. may be disposed between the first lower line wiring BMI and the second upper line wiring 320_2.

The second lower gate contact 175_2 may be disposed on the lower surface of the second lower gate electrode 140_2. The second lower line wiring BM2 may be disposed on a lower surface of the second lower gate contact 175_2. The second lower line wiring BM2 may extend in the first direction D1.

The second lower gate electrode 140_2 and the second upper gate electrode 240_2 may not be in direct contact with each other. The second lower gate electrode 140_2 may be electrically connected to the second upper gate electrode 240_2. For example, the second lower line wiring BM2 may be electrically connected to the first upper line wiring 320_1. A line wiring, a through via, etc. may be disposed between the second lower line wiring BM2 and the first upper line wiring 320_1.

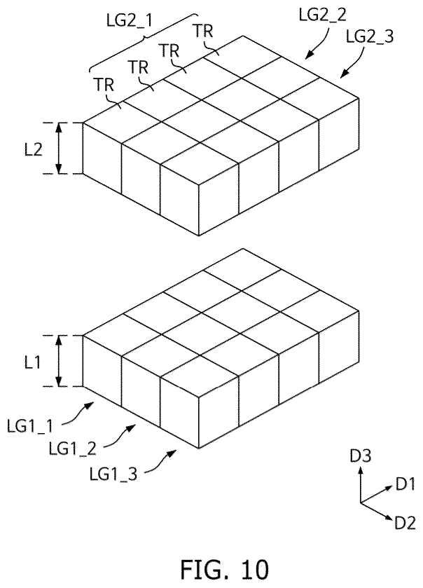

FIG. 10 is a schematic diagram provided to explain a semiconductor device according to one or more embodiments of the present disclosure.

Referring to FIG. 10, a semiconductor device according to one or more embodiments may include first to third lower line groups LG1_1, LG1_2, and LG1_3 disposed at the first level L1, and first to third upper line groups LG2_1, LG2_2, and LG2_3 disposed at the second level L2. The first level L1 and the second level L2 may overlap each other in the third direction D3. Although it is illustrated that the first level L1 and the second level L2 are spaced apart from each other in the third direction D3, this is only for convenience of description. It should be understood that the first level L1 and the second level L2 are, rather than being spaced apart from each other in the third direction D3 as illustrated in FIG. 2, connected to or stacked on each other.

Each of the first to third lower line groups LG1_1, LG1_2, and LG1_3 may be sequentially disposed in the second direction D2. In addition, each of the first to third upper line groups LG2_1, LG2_2, and LG2_3 may be sequentially disposed in the second direction D2.

Each of the first to third lower line groups LG1_1, LG1_2, and LG1_3 and the first to third upper line groups LG2_1, LG2_2, and LG2_3 may include four transistors TR. For example, the first upper line group LG2_1 may include four transistors TR. Each of the four transistors TR included in the first upper line group LG2_1 may be aligned in the first direction D1.

The semiconductor device of FIG. 10 may include a plurality of semiconductor devices of FIG. 2. For example, FIG. 10 may include various combinations of the semiconductor devices described with reference to FIG. 2.

For example, the transistor TR of each of the first lower line group LG1_1 and the third lower line group LG1_3 may be a P-type MOSFET. The transistor TR of each of the second lower line group LG1_2 and the first to third upper line groups LG2_1, LG2_2, and LG2_3 may be an N-type MOSFET. The transistor TR of each of the first lower line group LG1_1 and the third lower line group LG1_3 may be a pull-up transistor. The transistor TR of each of the second lower line group LG1_2 and the second upper line group LG2_2 may be a pass transistor. The transistor TR of each of the first upper line group LG2_1 and the third upper line group LG2_3 may be a pull-down transistor.

As another example, the transistor TR of each of the first to third lower line groups LG1_1, LG1_2, and LG1_3 and the second upper line group LG2_2 may be an N-type MOSFET. The transistor TR of each of the first upper line group LG2_1 and the third upper line group LG2_3 may be a P-type MOSFET. The transistor TR of each of the first lower line group LG1_1 and the third lower line group LG1_3 may be a pull-down transistor. The transistor TR of each of the second lower line group LG1_2 and the second upper line group LG2_2 may be a pass transistor. The transistor TR of each of the first upper line group LG2_1 and the third upper line group LG2_3 may be a pull-up transistor.

As another example, the transistor TR of each of the first lower line group LG1_1 and the third lower line group LG1_3 may be an N-type MOSFET. The transistor TR of each of the second lower line group LG1_2 and the first to third upper line groups LG2_1, LG2_2, and LG2_3 may be a P-type MOSFET. The transistor TR of each of the first lower line group LG1_1 and the third lower line group LG1_3 may be a pull-down transistor. The transistor TR of each of the second lower line group LG1_2 and the second upper line group LG2_2 may be a pass transistor. The transistor TR of each of the first upper line group LG2_1 and the third upper line group LG2_3 may be a pull-up transistor.

As another example, the transistor TR of each of the first to third lower line groups LG1_1, LG1_2, and LG1_3 and the second upper line group LG2_2 may be a P-type MOSFET. The transistor TR of each of the first upper line group LG2_1 and the third upper line group LG2_3 may be an N-type MOSFET. The transistor TR of each of the first lower line group LG1_1 and the third lower line group LG1_3 may be a pull-up transistor. The transistor TR of each of the second lower line group LG1_2 and the second upper line group LG2_2 may be a pass transistor. The transistor TR of each of the first upper line group LG2_1 and the third upper line group LG2_3 may be a pull-down transistor.

In one or more embodiments, the first to third lower line groups LG1_1, LG1_2, and LG1_3 and the first to third upper line groups LG2_1, LG2_2, and LG2_3 may repeat. For example, the first lower line group LG1_1, the second lower line group LG1_2, the third lower line group LG1_3, the first lower line group LG1_1, the second lower line group LG1_2, and the third lower line group LG1_3 may repeat in this order in the second direction D2. The first to third upper line groups LG2_1, LG2_2, and LG2_3 may also repeat in a corresponding order.

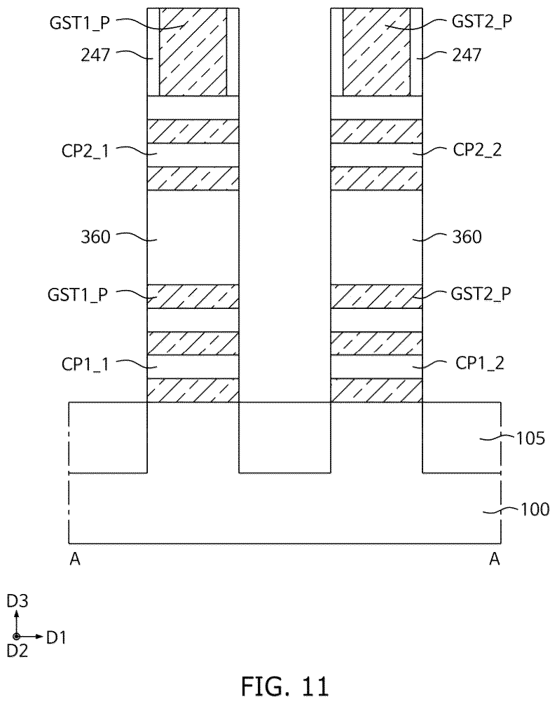

FIGS. 11 to 18 are diagrams showing intermediate stages, which are provided to explain a method for manufacturing a semiconductor device according to one or more embodiments of the present disclosure. For reference, FIGS. 11 to 18 are diagrams corresponding to cross-sectional diagrams taken along line A-A of FIGS. 3 and 4.

Referring to FIG. 11, the method for manufacturing the semiconductor device according to one or more embodiments may include forming, on the substrate 100, the first lower channel pattern CP1_1, the first upper channel pattern CP2_1, the second lower channel pattern CP1_2, the second upper channel pattern CP2_2, a first pre-gate structure GST1_P, and a second pre-gate structure GST2_P.

First, a stack structure in which sacrificial semiconductor layers and active semiconductor layers are alternately stacked on each other may be formed on the substrate 100. The substrate 100 may be a silicon substrate, or may include other materials, such as silicon germanium (SiGe), silicon germanium on insulator (SGOI), indium antimony, lead tellurium compound, indium arsenic, indium phosphide, gallium arsenic, or gallium antimony, but is not limited thereto.

A gate sacrificial pattern may be formed on the stack structure and a hard mask pattern may be formed on the gate sacrificial pattern. A source/drain trench may be formed in the stack structure by using the hard mask pattern as an etching mask. As a result, the first lower channel pattern CP1_1, the first upper channel pattern CP2_1, the second lower channel pattern CP1_2, the second upper channel pattern CP2_2, the first pre-gate structure GST1_P, and the second pre-gate structure GST2_P may be formed.

The first pre-gate structure GST1_P may be disposed on the first lower channel pattern CP1_1 and the first upper channel pattern CP2_1. The second pre-gate structure GST2_P may be disposed on the second lower channel pattern CP1_2 and the second upper channel pattern CP2_2.

When the source/drain trench is formed, the upper gate spacer 247 may be formed. The upper gate spacer 247 may be disposed on side surfaces of upper portions of the first and second pre-gate structures GST1_P and GST2_P.

The level isolation insulating film 360 may be disposed between the first lower channel pattern CP1_1 and the first upper channel pattern CP2_1. The level isolation insulating film 360 may be disposed between the second lower channel pattern CP1_2 and the second upper channel pattern CP2_2.

In one or more embodiments, a field insulating film 105 may be formed on the substrate 100.

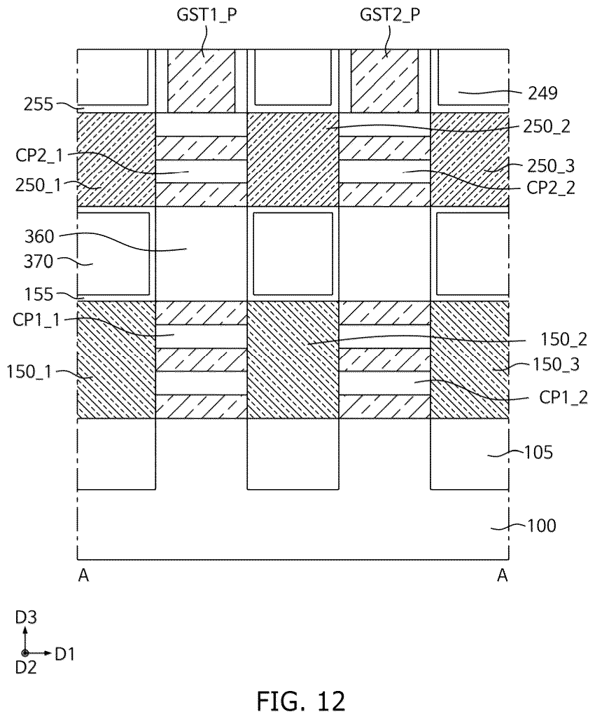

Referring to FIG. 12, the first lower source/drain pattern 150_1, the first upper source/drain pattern 250_1, the second lower source/drain pattern 150_2, the second upper source/drain pattern 250_2, the third lower source/drain pattern 150_3, the third upper source/drain pattern 250_3, etc. may be formed on the source/drain trench.

The lower etching stop film 155 may be formed on the first to third lower source/drain patterns 150_1, 150_2, and 150_3, and the intermediate insulating film 370 may be formed on the lower etching stop film. The first to third upper source/drain patterns 250_1, 250_2, and 250_3 may be formed on the intermediate insulating film 370. The upper etching stop film 255 may be formed on the first to third upper source/drain patterns 250_1, 250_2, and 250_3. The upper insulating film 249 may be formed on the upper etching stop film 255.

In one or more embodiments, the first to third lower source/drain patterns 150_1, 150_2, and 150_3 and the first to third upper source/drain patterns 250_1, 250_2, and 250_3 may be formed by different processes. Specifically, the first to third lower source/drain patterns 150_1, 150_2, and 150_3 may be formed using an epitaxial growth method. A passivation layer may be formed on the first to third lower source/drain patterns 150_1, 150_2, and 150_3. The first to third upper source/drain patterns 250_1, 250_2, and 250_3 may be formed using an epitaxial growth method. When the first to third upper source/drain patterns 250_1, 250_2, and 250_3 are formed, the fourth and fifth lower source/drain patterns 150_4 and 150_5 of FIG. 6 and the fourth and fifth upper source/drain patterns 250_4 and 250_5 of FIG. 6 may also be formed.

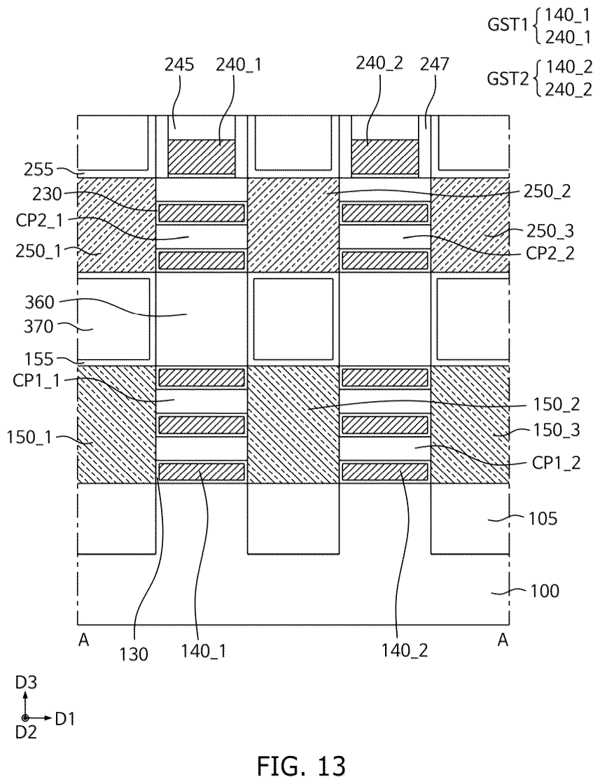

Referring to FIGS. 12 and 13, the first gate structure GST1 may be formed on the first lower channel pattern CP1_1 and the first upper channel pattern CP2_1, and the second gate structure GST2 may be formed on the second lower channel pattern CP1_2 and the second upper channel pattern CP2_2.

Specifically, each of the first pre-gate structure GST1_P and the second pre-gate structure GST2_P may be removed by a replacement process, and the first gate structure GST1 and the second gate structure GST2 may be formed thereon. The first lower gate electrode 140_1 may be disposed on the first lower channel pattern CP1_1. The first upper gate electrode 240_1 may be disposed on the first upper channel pattern CP2_1. The second lower gate electrode 140_2 may be disposed on the second lower channel pattern CP1_2. The second upper gate electrode 240_2 may be disposed on the second upper channel pattern CP2_2.

The upper gate capping patterns 245 may be formed on the upper surface of the first upper gate electrode 240_1 and the upper surface of the second upper gate electrode 240_2, respectively.

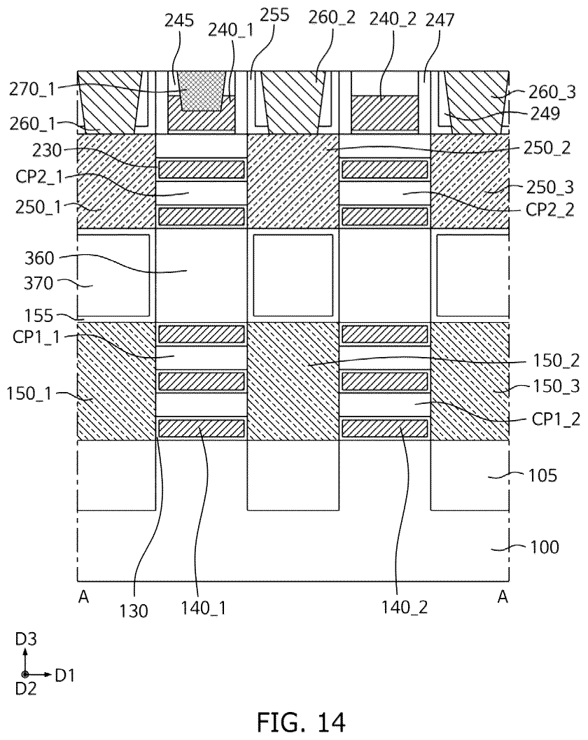

Referring to FIG. 14, the first to third upper source/drain contacts 260_1, 260_2, and 260_3 and the first upper gate contact 270_1 may be formed.

Specifically, the first upper source/drain contact 260_1 may be formed on the upper surface of the first upper source/drain pattern 250_1. The second upper source/drain contact 260_2 may be formed on the upper surface of the second upper source/drain pattern 250_2. The third upper source/drain contact 260_3 may be formed on the upper surface of the third upper source/drain pattern 250_3. The first to third upper source/drain contacts 260_1, 260_2, and 260_3 may extend through the upper insulating film 249.

The first upper gate contact 270_1 may be formed on the first upper gate electrode 240_1. The first upper gate contact 270_1 may extend through the upper gate capping pattern 245 and the upper surface of the first upper gate electrode 240_1.

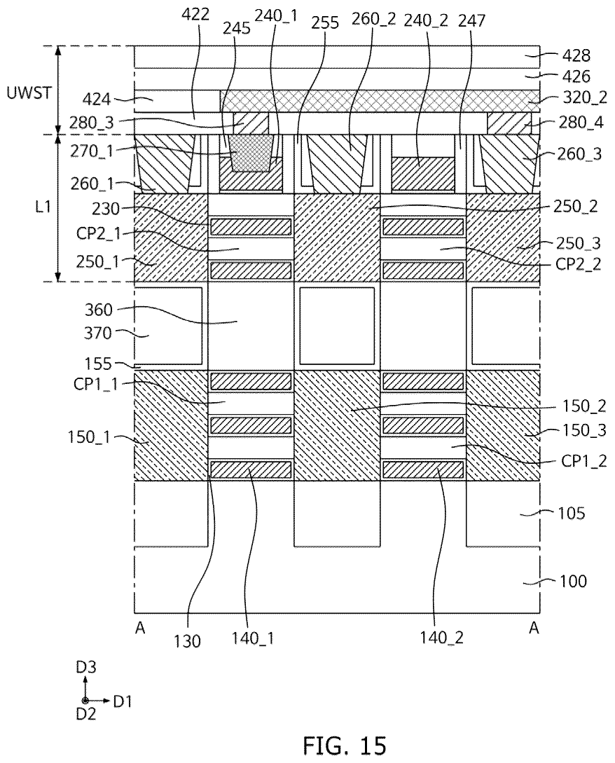

Referring to FIG. 15, the upper wiring structure UWST may be formed on the first to third upper source/drain contacts 260_1, 260_2, and 260_3 and the first upper gate contact 270_1. The upper wiring structure UWST may include first to fourth upper wiring insulating films 422, 424, 426, and 428, and wires disposed in the first to fourth upper wiring insulating films 422, 424, 426, and 428. The description of the upper wiring structure UWST may be the same as that described in FIGS. 3 to 7.

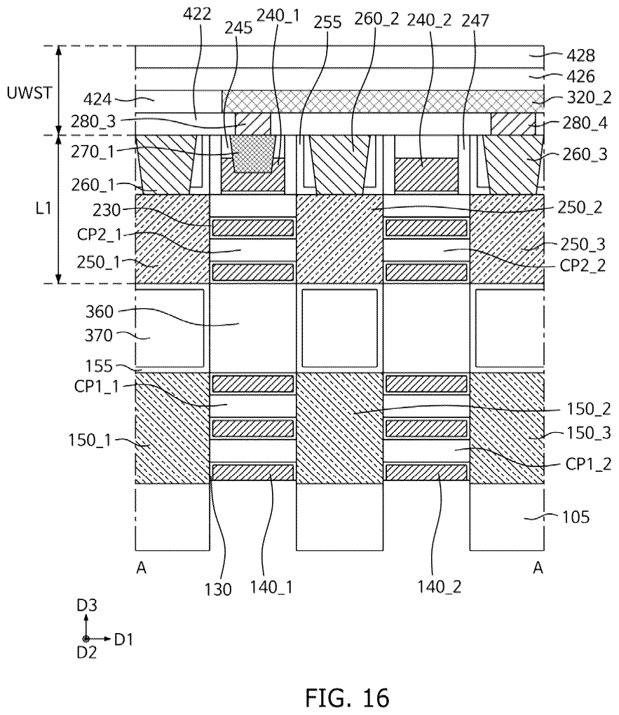

Referring to FIGS. 15 and 16, the substrate 100 may be removed. The substrate 100 may be removed to expose the field insulating film 105, the first lower gate electrode 140_1, and the second lower gate electrode 140_2.

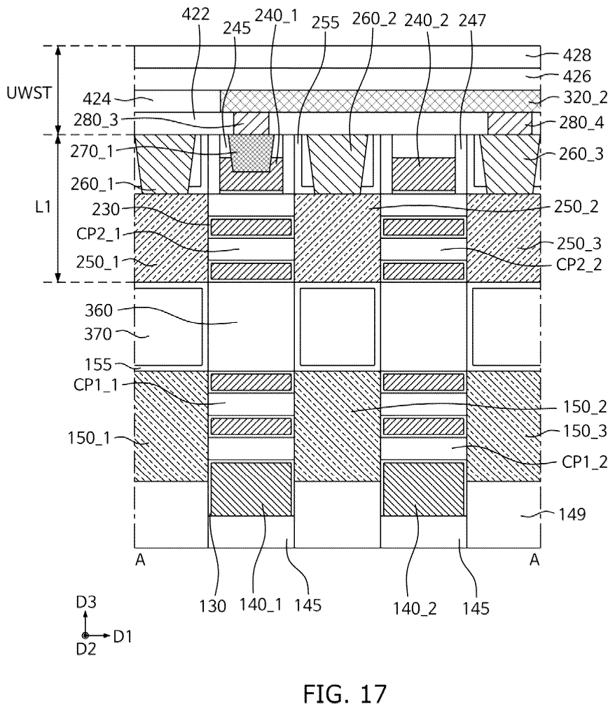

Referring to FIGS. 16 and 17, a gate electrode material may be further formed on the exposed first lower gate electrode 140_1 and the exposed second lower gate electrode 140_2. Accordingly, the lowermost portion of the first lower gate electrode 140_1 and the lowermost portion of the second lower gate electrode 140_2 may be disposed lower than the lower surface of the first lower source/drain pattern 150_1. However, aspects are not limited to the above. Unlike the illustration, the lower surface of the first lower gate electrode 140_1 and the lower surface of the second lower gate electrode 140_2 may be disposed flush with the lower surface of the first lower source/drain pattern 150_1.

In one or more embodiments, the field insulating film 105 may be removed, and the lower insulating film 149 may be formed. However, aspects are not limited to the above.

The lower gate capping pattern 145 may be formed on the lower surface of the first lower gate electrode 140_1 and the lower surface of the second lower gate electrode 140_2, respectively. The lower gate capping pattern 145 may have etch selectivity with respect to the lower insulating film 149.

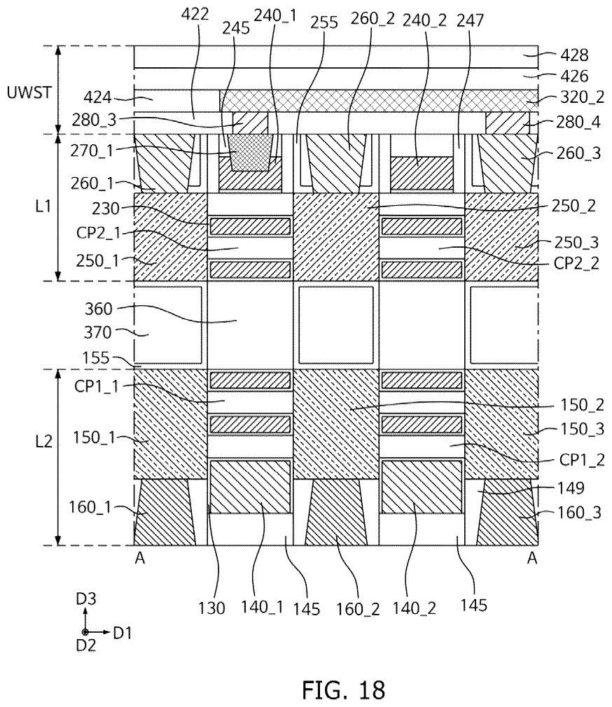

Referring to FIG. 18, the first to third lower source/drain contacts 160_1, 160_2, and 160_3 may be formed on the lower surface of each of the first to third lower source/drain patterns 150_1, 150_2, and 150_3. Each of the first to third lower source/drain contacts 160_1, 160_2, and 160_3 may extend through the lower insulating film 149.

Referring to FIG. 5, the lower wiring structure BWST may be formed under the first to third lower source/drain contacts 160_1, 160_2, and 160_3 and the lower insulating film 149.

Although certain aspects of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor device, comprising:
a first lower active pattern extending in a first direction and comprising a first lower channel pattern;
a second lower active pattern extending in the first direction and spaced apart from the first lower active pattern in a second direction intersecting the first direction, wherein the second lower active pattern comprises a second lower channel pattern;
a first upper active pattern extending in the first direction and spaced apart from the first lower active pattern in a third direction intersecting the first direction and the second direction, wherein the first upper active pattern comprises a first upper channel pattern;
a second upper active pattern extending in the first direction and spaced apart from the second lower active pattern in the third direction, wherein the second upper active pattern comprises a second upper channel pattern;
a first gate structure extending in the second direction and intersecting the first lower active pattern and the first upper active pattern;
a second gate structure extending in the second direction and intersecting the second lower active pattern and the second upper active pattern;
a first lower source/drain pattern disposed on one side of the first lower channel pattern;
a first upper source/drain pattern disposed on one side of the first upper channel pattern;
a second lower source/drain pattern disposed on one side of the second lower channel pattern; and
a second upper source/drain pattern disposed on one side of the second upper channel pattern,
wherein the first lower source/drain pattern and the first upper source/drain pattern have different conductivity types, and
wherein the second lower source/drain pattern and the second upper source/drain pattern have the same conductivity type.

2. The semiconductor device according to claim 1,
wherein the first lower source/drain pattern and the first upper source/drain pattern overlap in the third direction, and
wherein the second lower source/drain pattern and the second upper source/drain pattern overlap in the third direction.

3. The semiconductor device according to claim 1, wherein the first gate structure and the second gate structure overlap in the second direction.

4. The semiconductor device according to claim 1,
wherein the first lower source/drain pattern and the first upper source/drain pattern are electrically connected, and
wherein the first lower source/drain pattern and the second lower source/drain pattern are electrically connected.

5. The semiconductor device according to claim 1,
wherein the first gate structure comprises a first lower gate electrode around the first lower channel pattern, and a first upper gate electrode around the first upper channel pattern, and
wherein the first lower gate electrode and the first upper gate electrode are electrically connected.

6. The semiconductor device according to claim 1,
wherein the second gate structure comprises a second lower gate electrode around the second lower channel pattern, and a second upper gate electrode around the second upper channel pattern, and
wherein the second lower gate electrode and the second upper gate electrode are electrically connected.

7. The semiconductor device according to claim 6, further comprising:
a gate contact disposed on at least one of the second lower gate electrode and the second upper gate electrode,
wherein the gate contact is electrically connected to a word line.

8. The semiconductor device according to claim 1, wherein the first lower active pattern further comprises a third lower channel pattern spaced apart from the first lower channel pattern in the first direction, and the first upper active pattern further comprises a third upper channel pattern spaced apart from the first upper channel pattern in the first direction, the semiconductor device further comprising:
a third gate structure spaced apart from the first gate structure in the first direction and around the third lower channel pattern and the third upper channel pattern.

9. The semiconductor device according to claim 8, further comprising:
a third lower source/drain pattern disposed between the first lower channel pattern and the third lower channel pattern; and
a first power line disposed below the first lower active pattern,
wherein the third lower source/drain pattern is electrically connected to the first power line.

10. The semiconductor device according to claim 1, further comprising:
a third gate structure spaced apart from the first gate structure in the first direction and intersecting the first lower active pattern and the first upper active pattern,
wherein the first upper source/drain pattern is electrically connected to the third gate structure.

11. The semiconductor device according to claim 8, further comprising:
a third upper source/drain pattern disposed between the first upper channel pattern and the third upper channel pattern; and
a second power line disposed below the first lower active pattern,
wherein the third upper source/drain pattern is electrically connected to the second power line.

12. The semiconductor device according to claim 11, further comprising:
an upper source/drain contact disposed on the third upper source/drain pattern; and
a through via extending in the third direction and electrically connecting the upper source/drain contact and the second power line.

13. The semiconductor device according to claim 1, wherein the first lower channel pattern and the first upper channel pattern comprise a plurality of sheet patterns.

14. A semiconductor device, comprising:
a first transistor group disposed at a first level, wherein the first transistor group comprises a first pull-up transistor, a second pull-up transistor, and a first pass transistor;
a second transistor group disposed at a second level different from the first level, wherein the second transistor group comprises a first pull-down transistor, a second pull-down transistor, and a second pass transistor;
a first power line connected to a source pattern of the first pull-up transistor; and
a second power line connected to a source pattern of the first pull-down transistor,
wherein a drain pattern of the first pull-up transistor, a drain pattern of the first pull-down transistor, and a drain pattern of the first pass transistor are electrically connected through a first node,
wherein a drain pattern of the second pull-up transistor, a drain pattern of the second pull-down transistor, and a drain pattern of the second pass transistor are electrically connected through a second node,
wherein the first pass transistor and the second pass transistor overlap in a first direction,
wherein the first pull-up transistor and the first pull-down transistor overlap in the first direction, and
wherein the first direction is perpendicular to an upper surface of the first power line.

15. The semiconductor device according to claim 14, wherein the first node is electrically connected to a gate of the second pull-up transistor and to a gate of the second pull-down transistor.

16. The semiconductor device according to claim 14,
wherein the first pull-up transistor and the second pull-up transistor are disposed on an active pattern extending in a second direction intersecting the first direction, and
wherein the first pull-up transistor and the second pull-up transistor share one source pattern.

17. The semiconductor device according to claim 14, further comprising:
a lower source/drain contact directly connected to a lower portion of the source pattern of the first pull-up transistor,
wherein the lower source/drain contact is electrically connected to the first power line.

18. The semiconductor device according to claim 14, wherein the first pass transistor and the second pass transistor share a gate electrode.

19. The semiconductor device according to claim 14,
wherein the first pull-up transistor and the second pull-up transistor are first conductivity type transistors,
wherein the first pull-down transistor and the first pass transistor are second conductivity type transistors, and
wherein the first conductivity type transistors have a different conductivity type from the second conductivity type transistors.

20. A semiconductor device, comprising:
a first lower active pattern extending in a first direction;
a second lower active pattern extending in the first direction and spaced apart from the first lower active pattern in a second direction intersecting the first direction;
a first upper active pattern extending in the first direction and spaced apart from the first lower active pattern in a third direction intersecting the second direction;
a second upper active pattern extending in the first direction and spaced apart from the second lower active pattern in the third direction;
a first pull-up transistor and a second pull-up transistor disposed on the first lower active pattern;
a first pull-down transistor and a second pull-down transistor disposed on the first upper active pattern;
a first pass transistor disposed on the second lower active pattern;
a second pass transistor disposed on the second upper active pattern;
a first power line connected to a source pattern of the first pull-up transistor; and
a second power line connected to a source pattern of the first pull-down transistor, wherein
the first power line and the second power line are disposed below the first lower active pattern,
a drain pattern of the first pull-up transistor, a drain pattern of the first pull-down transistor, and a drain pattern of the first pass transistor are electrically connected through a first node,
a drain pattern of the second pull-up transistor, a drain pattern of the second pull-down transistor, and a drain pattern of the second pass transistor are electrically connected through a second node,
the first pass transistor and the second pass transistor overlap in the third direction, and
the first pass transistor, the second pass transistor, the first pull-down transistor, the second pull-down transistor, the first pull-up transistor, and the second pull-up transistor comprise a plurality of sheet patterns.

21. (canceled)
